(19) United States
(12) Patent Application Publication
(10) Pub. No.: US 2026/0040473 A1
(43) Pub. Date: Feb. 5, 2026

(54) FIXING MEMBER AND ELECTRONIC DEVICE

(71) Applicant: LITE-ON Technology Corporation, Taipei City (TW)

(72) Inventors: Yung-Chou LI, Taipei City (TW); Tsung-Po HSU, Taipei City (TW); Chen-Huei HUANG, Taipei City (TW)

(21) Appl. No.: 19/084,786

(22) Filed: Mar. 20, 2025

(30) Foreign Application Priority Data
Jul. 31, 2024 (CN) 2024110386505

(51) Int. Cl. H05K 7/14

(52) U.S. Cl. CPC H05K 7/1405

(57) ABSTRACT

The present invention discloses a fixing member and an electronic device including the same. The fixing member includes a first block, a second block, two board bodies, and an elastic piece. The first and second blocks extend in the first direction and are parallelly spaced apart by a distance in the second direction. Two board bodies are set on the first block, extending in the second direction, and are parallel to each other. The elastic piece is positioned between the two board bodies, extending from the first block in the second direction and has a protruding part in the third direction. The first and second directions are orthogonal, the third direction is orthogonal to the first and second directions. By fitting the plate-like element between the first and second blocks, the plate-like element is stably fixed within the housing, improving yield rate of electronic products.

### CROSS-REFERENCE TO RELATED APPLICATION

This application claims the priority benefit of Chinese Patent Application Serial Number 2024110386505, filed on Jul. 31, 2024, the full disclosure of which is incorporated herein by reference.

### BACKGROUND

### 1. Technical Field

The present invention relates to the technical field of fixing structures, and particularly to a fixing member for an electronic device.

### 2. Description of the Related Art

Existing electronic products, such as power supply products or input devices, typically have a housing and various internal electronic components including plate-like elements such as printed circuit boards. Generally, the plate-like elements are securely fixed within the housing by means of screw fasteners such that the plate-like elements are stably secured inside the housing. This prevents the plate-like elements from moving when the product is subjected to impacts or jolts, which could otherwise cause damage to the components or wirings connected to the plate-like elements, leading to product malfunctions.

Screw fasteners are generally made of metal. Since copper foils on the plate-like elements, such as printed circuit boards, transmit different voltages and must not come into contact with one another, it is necessary to maintain a distance between the copper foils carrying different voltages and provide sufficient space for the screw fasteners to avoid potential contact of copper foils via the screw fasteners.

However, as the size of modern electronic products is getting smaller, space available for screw fasteners on the printed circuit boards becomes insufficient once electronic components are mounted. This lack of adequate fastening space can lead to product failure when subjected to jolts or drops. Even if the components are secured by screw fasteners to pass product tests, electrical failures may occur due to unintended contact caused by the screw fasteners between areas with different voltages.

Therefore, there is indeed a need for further improvements to the current technology to address these issues.

### SUMMARY

In view of the deficiencies in the prior art, the main objective of this invention is to provide a fixing member and an electronic device including the same. By utilizing a fitting space and an elastic piece of the fixing member, the plate-like element can be secured within the housing, thereby improving product yield rate.

To achieve the aforementioned objectives, the primary technical approach adopted in the present invention is to configure the fixing member to include: a first block and a second block, wherein the first block and the second block extend along a first direction, and the first block and the second block are parallel to each other and spaced apart by a distance in a second direction; two board bodies, disposed on the first block and extending from the first block along the second direction, wherein the two board bodies are arranged in parallel; an elastic piece, disposed on the first block and extending from the first block along the second direction, and positioned between the two board bodies, wherein the elastic piece includes a protruding part in a third direction; wherein the first direction is orthogonal to the second direction, and the third direction is orthogonal to both the first direction and the second direction.

Preferably, the first block and the second block extend beyond outer side surfaces of the two board bodies at both ends in the first direction.

Preferably, the elastic piece comprises a connecting part and a top, wherein one end of the connecting part is connected to the first block and another end of the connecting part is connected to the top. A top surface of the top protrudes relative to top surfaces of the two board bodies in the second direction.

Preferably, the protruding part is positioned between the connecting part and the top.

Preferably, the connecting part is inclined from the first block in the third direction and is bent and extended to form the protruding part.

Preferably, the protruding part includes a supporting surface, and the supporting surface extends along the third direction.

Preferably, a curved surface is formed to connect a front side surface and a bottom surface of the first block or connect a top surface and a front surface of the second block.

Preferably, the fixing member further comprises a rear side wing extending from a rear side surface of the first block along the second direction toward a rear side surface of the second block.

Preferably, the rear side wing includes a through hole between the first block and the second block.

Preferably, the rear side wing has one end extending beyond one end of the first block in the first direction or the rear side wing has one end extending beyond one end of the second block in the first direction, and the rear side wing includes a curved surface.

Preferably, the rear side wing is connected to a top surface of the first block or a bottom surface of the second block in a curved manner.

Preferably, a bottom surface of the rear side wing extends to connect with a bottom surface of the second block on the same plane.

By utilizing the aforementioned configurations, the first block and the second block are spaced apart in the second direction by a distance to accommodate fitting of the plate-like element. The plate-like element is then fixed to the housing via the elastic piece. In this way, the plate-like element can be stably fixed within the housing without occupying a large amount of space on the plate-like element, thereby improving the product's yield rate. By moving the elastic piece, the plate-like element can also be easily removed from the housing along with the fixing member, without the need for additional tools, thus facilitating maintenance.

### BRIEF DESCRIPTION OF THE DRAWINGS

The accompanying drawings presented herein serve for comprehension of the present invention and are an integral part thereof. The illustrative embodiments and their explanations are provided to elucidate the present invention but do not intend to impose any limitations on it. In the drawings:

FIG. 1 is a perspective view of the fixing member according to the present invention;

FIG. 2 is a front view of the fixing member according to the present invention;

FIG. 3 is a rear view of the fixing member according to the present invention;

FIG. 4 is a sectional view along line A-A in FIG. 3;

FIG. 5 is a side view of the fixing member according to the present invention;

FIG. 6 is an exploded view illustrating the embodiment of the fixing member in FIG. 1 combined with a plate-like element;

FIG. 7 is a perspective view of another embodiment of the fixing member according to the present invention;

FIG. 8 is a sectional view along line B-B in FIG. 7;

FIG. 9 is a schematic view of the fixing member in FIG. 1 combined with the plate-like element; and

FIG. 10 is a sectional view along line C-C in FIG. 9.

### DETAILED DESCRIPTION OF THE EMBODIMENTS

The following describes the technical features of embodiments of the present invention in conjunction with the relevant drawings. The described embodiments serve illustrate the essential parts of implementing the present invention, rather than limiting them. It is understood that any other modifications obtained by a person having ordinary skills in the art based on the embodiments of the present invention without requiring inventive effort also fall within the scope of protection of the present invention.

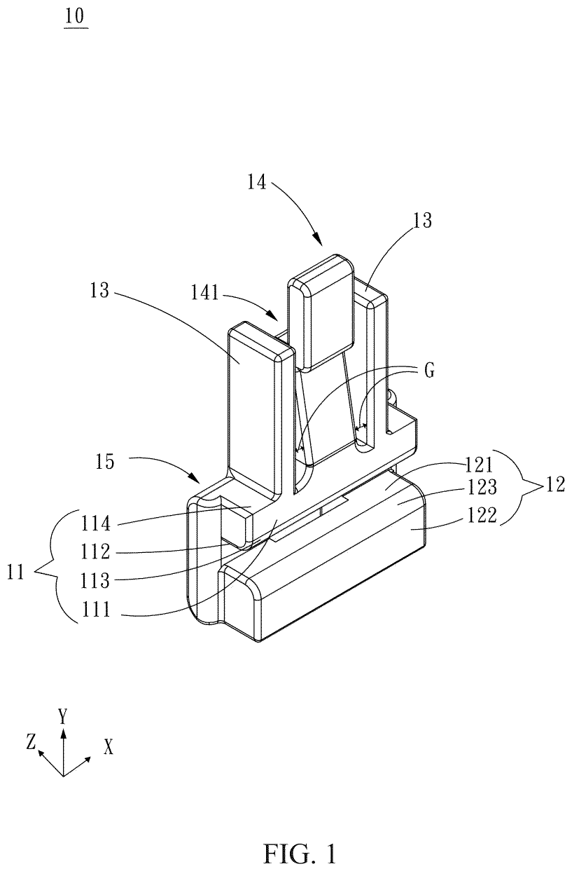

FIG. 1 is a perspective view of the fixing member according to the present invention. As shown in FIG. 1, the fixing member 10 of the present invention includes a first block 11, a second block 12, two board bodies 13, and an elastic piece 14. The first block 11 and the second block 12 extend along a first direction X and are spaced apart by a distance and arranged parallel to each other in a second direction Y. The two board bodies 13 are positioned above the first block 11 and extend from the first block 11 along the second direction Y. The two board bodies 13 are arranged parallel to each other. The elastic piece 14 is positioned on the first block 11 and extends from the first block 11 along the second direction Y, situated between the two board bodies 13. The elastic piece 14 has a protruding part 141 protruding in the third direction Z. The aforementioned first direction X and second direction Y are orthogonal to each other, and the third direction Z is orthogonal to both the first direction X and the second direction Y. Preferably, the fixing member 10 can be made of a non-conductive material.

Specifically, the first block 11 and the second block 12 are arranged parallel to each other and are spaced apart by a distance in the second direction Y to form a fitting space, which accommodates a portion of the plate-like element. Preferably, the front side surface 111 and the bottom surface 112 of the first block 11 may be connected by a curved surface 113, the top surface 121 and the front side surface 122 of the second block 12 may be connected by a curved surface 123, for guiding the plate-like element (such as a printed circuit board) into the fitting space. The top surface 114 of the first block 11 is provided with the two board bodies 13 and the elastic piece 14. The elastic piece 14 is positioned between the two board bodies 13, so the movement of the elastic piece 14 is restricted between the two board bodies 13. Additionally, a gap G is configured between the elastic piece 14 and the two board bodies 13 such that the two board bodies 13 can move with respect to the elastic piece 14.

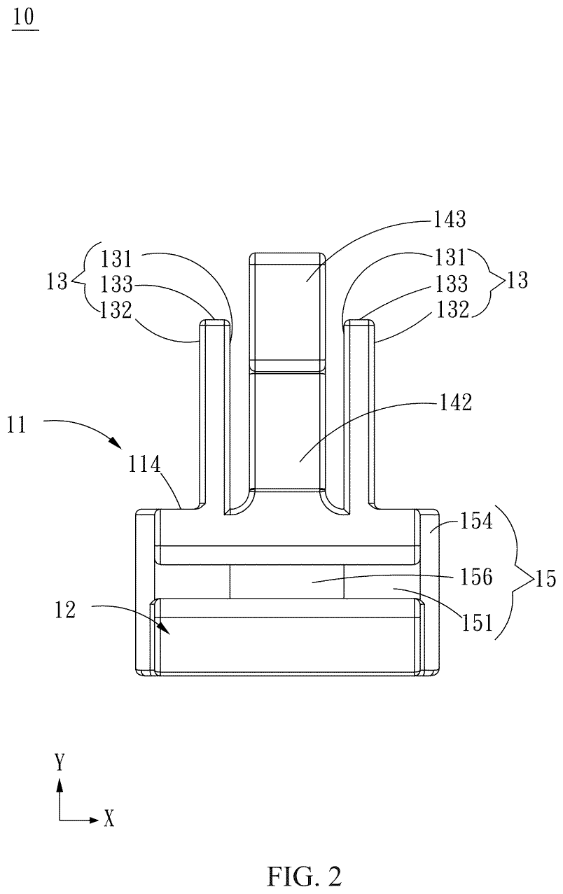

FIG. 2 is a front view of the fixing member according to the present invention. As shown in FIG. 2, the sides of the two board bodies 13 that are close to the elastic piece 14 are the inner side surfaces 131, while the sides of the two board bodies 13 that are away from the elastic piece 14 are the outer side surfaces 132. The first block 11 and the second block 12 extend beyond the outer side surfaces 132 of the two board bodies 13 at both ends in the first direction X.

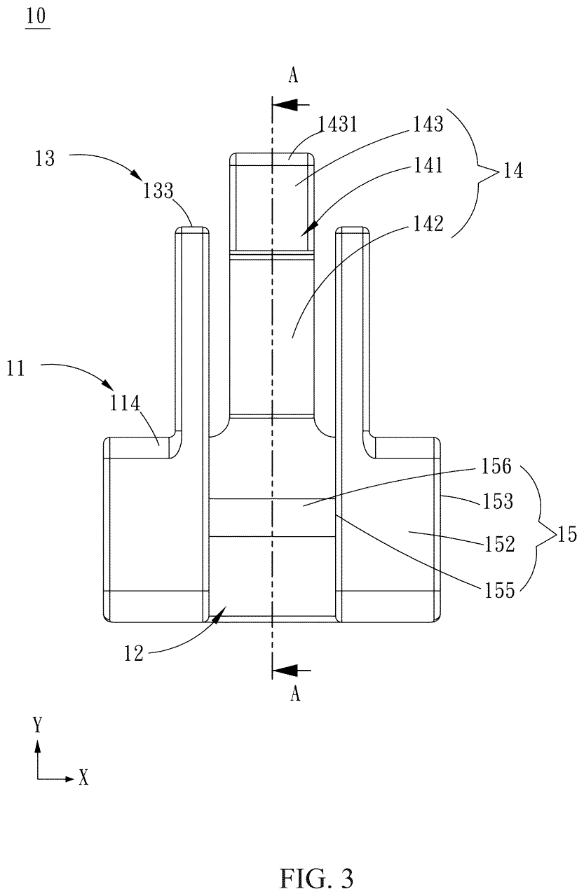

FIG. 3 is a rear view of the fixing member according to the present invention. As shown in FIGS. 1, 2, and 3, the elastic piece 14 further includes a connecting part 142 and a top 143. One end of the connecting part 142 is connected to the top surface 114 of the first block 11, while another end of the connecting part 142 is connected to the top 143. The top surface 1431 of the top 143 protrudes with respect to the top surfaces 133 of the two board bodies 13 in the second direction Y. When a user needs to install or remove the fixing member 10 of the present invention, the top 143, which extends higher than the two board bodies 13, provides an accessible location for the user to apply force in the third direction Z to the elastic piece 14.

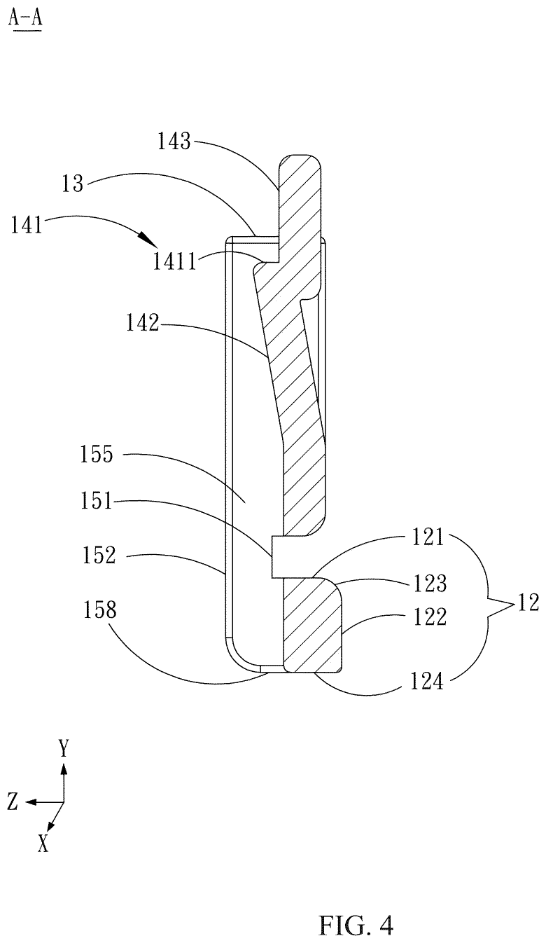

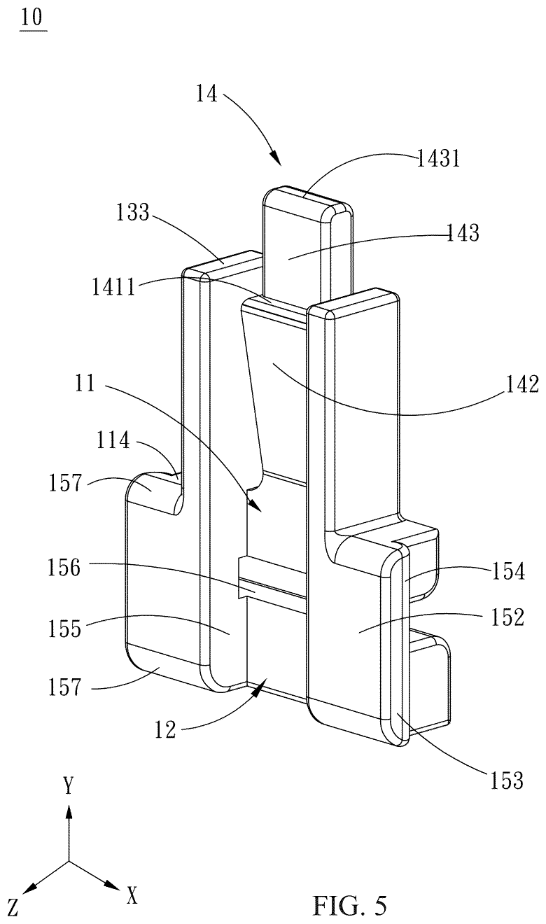

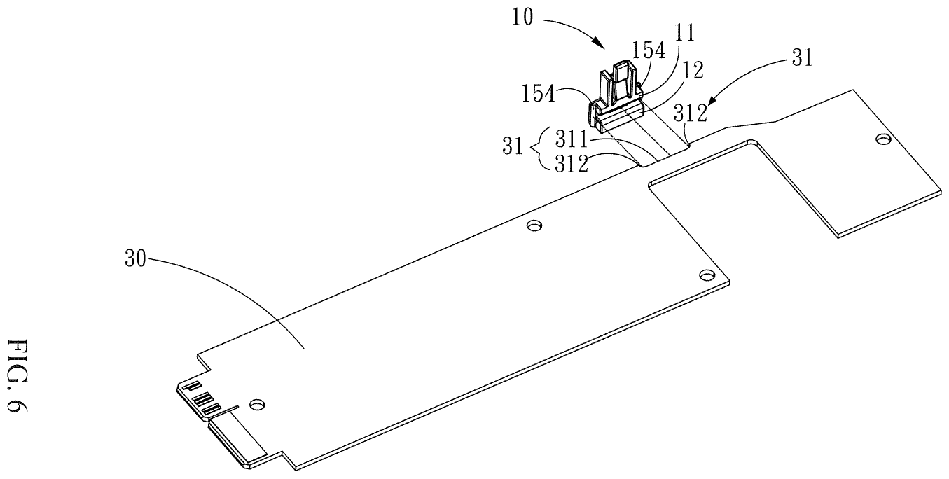

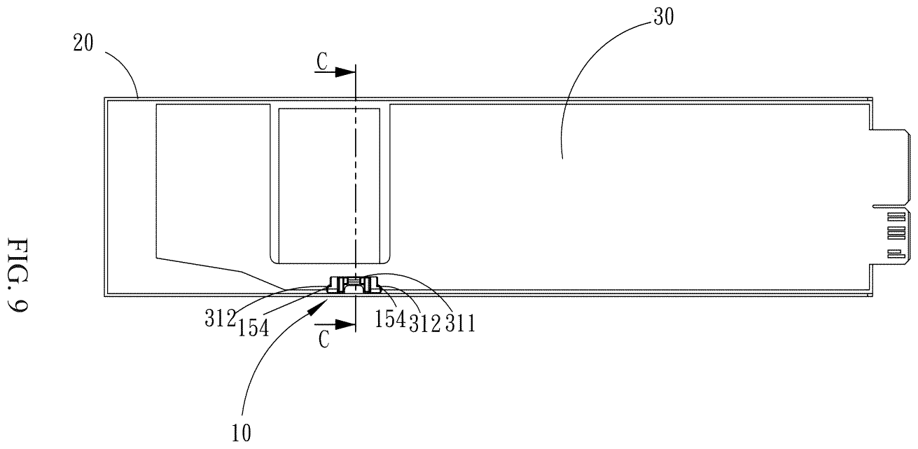

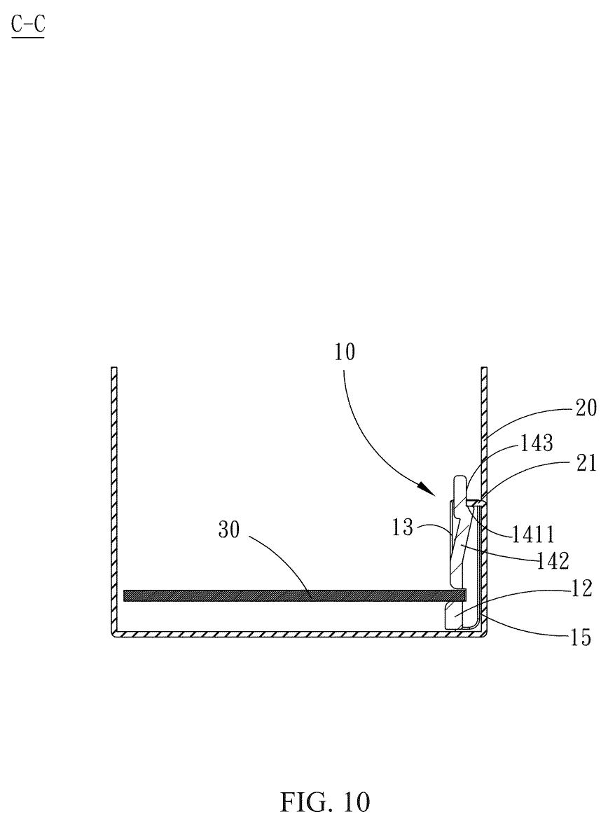

FIG. 4 is a cross-sectional view along line A-A in FIG. 3. The A-A cross-section is taken along the second direction Y from the middle of the elastic piece 14 toward the second block 12. FIG. 5 is a rear side view of the fixing member according to the present invention. FIG. 6 is an exploded view showing the embodiment of FIG. 1 combined with a plate-like element. As shown in FIGS. 2, 4, 5, and 6, the fixing member 10 further includes a rear side wing 15. The rear side wing 15 extends from the rear side surface of the first block 11 in the second direction Y toward the rear side surface of the second block 12. The front side surface 151 of the rear side wing 15 is positioned between the first block 11 and the second block 12. When the plate-like element 30 is inserted into the fitting space, one side of the plate-like element 30 is abutted against the front side surface 151 of the rear side wing 15, thereby stabilizing it within the fitting space. The rear side surface 152 of the rear side wing 15 can abut against the inner wall of the housing 20 (as shown in FIGS. 9 and 10), ensuring that the fixing member 10 is securely positioned within the housing 20. Preferably, one outer end 153 of the rear side wing 15 extends beyond one outer end of the first block 11 in the first direction X and/or extends beyond one outer end of the second block 12 in the first direction X and has a curved surface 154. By this arrangement, when the fixing member 10 is combined to the plate-like element 30 via slot 31 thereof, the curved surface 154 could fill the empty space in the slot 31 to ensure a snug fit with the plate-like element 30 for a more stable fixation, preventing displacement of the plate-like element 30 along the first direction X. Specifically, the slot 31 of the plate-like element 30 includes an inner contact surface 311 and a concave surface 312. The front side surface 151 of the rear side wing 15 is close to the inner contact surface 311, while the curved surface 154 is close to the concave surface 312. By this design, the fixing member 10 can fit precisely with the slot 31 of the plate-like element 30. Since the curved surface 154 is designed to stabilize the connection with the slot 31 of the plate-like element 30 and prevent displacement, any shape or structure that achieves the same effect is considered within the scope of the present invention, and the present invention is not limited to the curved surface 154. Preferably, the inner end 155 of the rear side wing 15 extends from the inner side surfaces 131 of the two board bodies 13, creating a through hole 156 between the inner end 155 of the rear side wing 15 with the first block 11 and the second block 12. The through hole 156 allows the fixing member 10 be deformable in the second direction Y, capable of accommodating plate-like elements in various thicknesses.

In one embodiment, the rear side wing 15 is connected to the top surface 114 of the first block 11 and/or the bottom surface 124 of the second block 12 by a connecting surface 157. Preferably, the connecting surface 157 is curved. In this embodiment, the bottom surface 158 of the rear side wing 15 and the bottom surface 124 of the second block 12 may extend to connect on the same plane such that the fixing member 10 can be stably placed on the bottom surface of the housing 20 (as shown in FIGS. 9 and 10). In this embodiment, there are two rear side wings 15, and each rear side wing 15 is correspondingly arranged with the one of the board bodies 13.

In one embodiment, still as shown in FIG. 4, the protruding part 141 is positioned between the connecting part 142 and the top 143, and protrudes in the third direction Z. In this embodiment, the protruding part 141 is formed on the rear side surface of the elastic piece 14. Specifically, the connecting part 142 extends from the first block 11 in the second direction Y while inclining toward the third direction Z and then bends and extends to form the protruding part 141. Through the arrangement of the connecting part 142, the protruding part 141, and the top 143, the elastic piece 14 presents a Z-like shape when viewed from the side. The top of the protruding part 141 forms a supporting surface 1411. The supporting surface 1411 extends along the third direction Z.

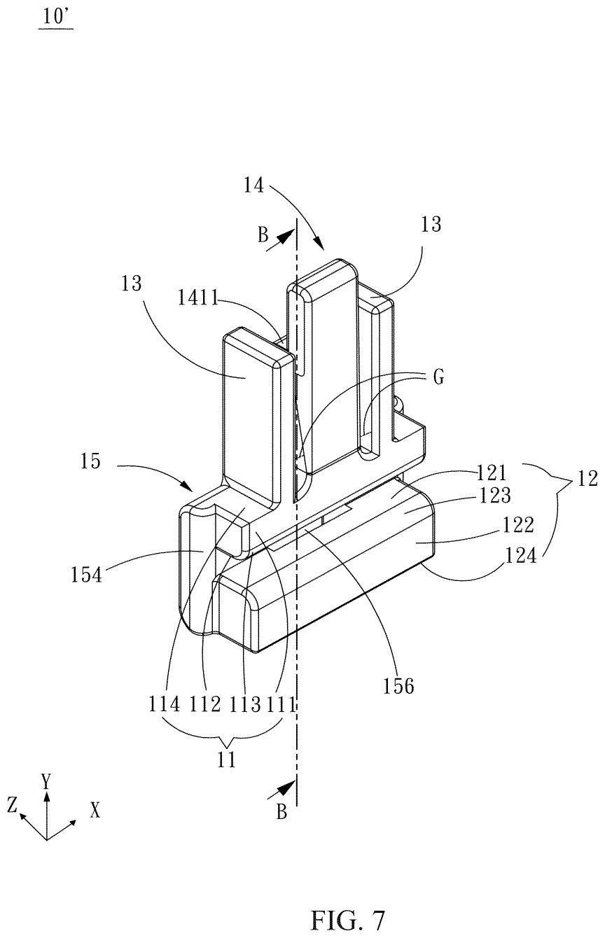

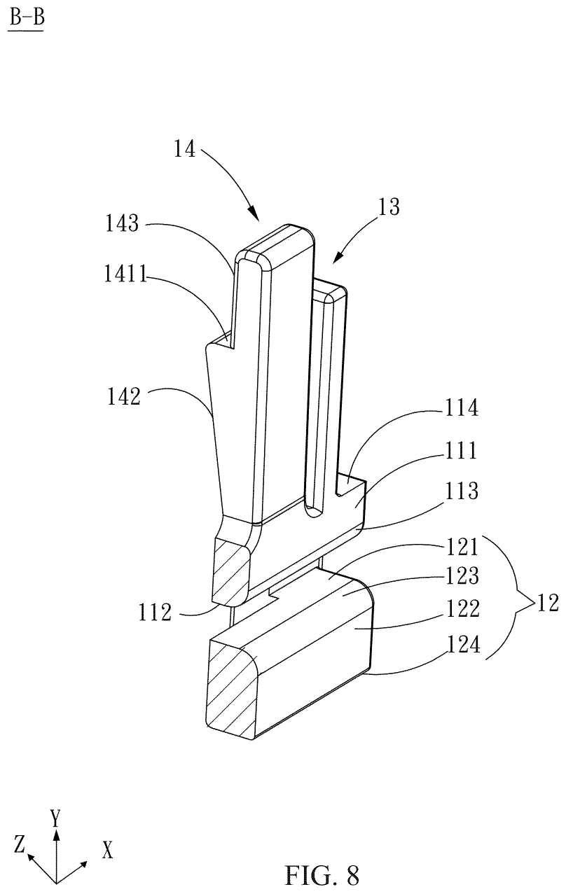

Additionally, FIG. 7 illustrates a perspective view of another embodiment of the fixing member 10′ of this invention. FIG. 8 shows a cross-sectional view along line B-B in FIG. 7. The B-B cross-sectional view is taken along the second direction Y, through the gap G between the elastic piece 14 and one of the board bodies 13. As shown in FIGS. 7 and 8, this embodiment is generally similar to the previously described embodiments, so detailed descriptions are omitted for common features. In this embodiment, the elastic piece 14 may be a flat piece extending along the second direction Y, with the protruding part 141 being a protrusion with an inclined surface and including a supporting surface 1411 in the third direction Z. The protruding part 141 may also be in the form of a block-shaped protrusion, a rounded bulge, or other forms, it may either be a separate component or integrally formed on the elastic piece 14 in the third direction Z.

To clearly illustrate the invention of the fixing member in an electronic device, FIG. 9 shows a schematic view of the fixing member from FIG. 1 combined with a plate-like element, and FIG. 10 shows a cross-sectional view along line C-C in FIG. 9. As shown in FIGS. 9 and 10, the electronic device includes the fixing member 10, a housing 20, and a plate-like element 30. An engagement part 21 is formed on the side of the housing 20. In one embodiment, a side of the housing 20 has a part inwardly folded near the middle to form the engagement part 21, though the invention is not limiting thereto.

In the aforementioned embodiments, when the user intends to fix the plate-like element 30 inside the housing 20 using the fixing member 10, the user first grips the two board bodies 13 and moves the fixing member 10 near the plate-like element 30, fitting the plate-like element 30 between the first block 11 and the second block 12 of the fixing member 10. The fixing member 10, along with the plate-like element 30, is then moved closer to the engagement part 21 of the housing 20, positioning the engagement part 21 between the two board bodies 13 of the fixing member 10. The top 143 of the elastic piece 14 is operated such that the supporting surface 1411 of the elastic piece 14 is abutted against the bottom surface of the engagement part 21, thereby securing the fixing member 10 to the side of the housing 20 and consequently fixing the plate-like element 30 within the housing 20. When the user intends to detach the plate-like element 30 from the housing 20, the user exerts force to the top 143 of the elastic piece 14 in a direction away from the engagement part 21 so as to move the supporting surface 1411 of the elastic piece 14 away from the bottom surface of the engagement part 21, thereby allowing the user to easily lift and remove the fixing member 10 along with the plate-like element 30.

In summary, by using the rear side wing 15 of the fixing member 10 to support the inner sidewall of the housing 20 and the plate-like element 30, the plate-like element 30 fitted between the first block 11 and the second block 12 can be stably fixed in the lateral direction of electronic devices. Through the pressing engagement force exerted by the elastic piece 14 on the engagement part 21, the plate-like element 30 can be stably fixed in the vertical direction. In this way, the plate-like element 30 can be secured without much space thereon be occupied, thereby enhancing the product yield rate.

It should be noted that in this document, the terms “include” and “comprise,” and any variations thereof, are intended to cover a non-exclusive inclusion, so that a process, method, article, or apparatus that comprises a list of elements not only includes those elements but may also include other elements not expressly listed or inherent to such process, method, article, or apparatus. Without further limitations, elements defined by the phrase “comprising a . . . ” do not exclude the presence of additional identical elements in the process, method, article, or apparatus that comprises the element.

It should be noted that the embodiments given above are examples rather than limitations of the present invention. Any combination and variation without departing from the fundamental structure of the invention are to be encompassed within the scope of protection in accordance with the broadest interpretation of the appended claims.

What is claimed is:

1. A fixing member, comprising:
a first block and a second block, wherein the first block and the second block extend along a first direction, and the first block and the second block are parallel to each other and spaced apart by a distance in a second direction;
two board bodies, disposed on the first block and extending from the first block along the second direction, wherein the two board bodies are arranged in parallel; and
an elastic piece, disposed on the first block, extending from the first block along the second direction, and positioned between the two board bodies, wherein the elastic piece includes a protruding part in a third direction; wherein the first direction is orthogonal to the second direction, and the third direction is orthogonal to both the first direction and the second direction.

2. The fixing member as claimed in claim 1, wherein the first block and the second block extend beyond outer side surfaces of the two board bodies at both ends in the first direction.

3. The fixing member as claimed in claim 1, wherein the elastic piece comprises a connecting part and a top, one end of the connecting part is connected to the first block, another end of the connecting part is connected to the top, and a top surface of the top protrudes relative to top surfaces of the two board bodies in the second direction.

4. The fixing member as claimed in claim 3, wherein the protruding part is positioned between the connecting part and the top.

5. The fixing member as claimed in claim 3, wherein the connecting part is inclined from the first block in the third direction and is bent and extended to form the protruding part.

6. The fixing member as claimed in claim 1, wherein the protruding part includes a supporting surface, the supporting surface extends along the third direction.

7. The fixing member as claimed in claim 1, wherein a curved surface is formed to connect a front side surface and a bottom surface of the first block or connect a top surface and a front surface of the second block.

8. The fixing member as claimed in claim 1, further comprising:
a rear side wing, wherein the rear side wing extends from a rear side surface of the first block along the second direction toward a rear side surface of the second block.

9. The fixing member as claimed in claim 8, wherein the rear side wing includes a through hole between the first block and the second block.

10. The fixing member as claimed in claim 8, wherein the rear side wing has one end extending beyond one end of the first block in the first direction or the rear side wing has one end extending beyond one end of the second block in the first direction, and the rear side wing includes a curved surface.

11. The fixing member as claimed in claim 8, wherein the rear side wing is connected to a top surface of the first block or a bottom surface of the second block in a curved manner.

12. The fixing member as claimed in claim 8, wherein a bottom surface of the rear side wing extends to connect with a bottom surface of the second block on the same plane.

13. An electronic device, comprising the fixing member as claimed in claim 1.
